(19) United States
(12) Patent Application Publication
(10) Pub. No.: US 2024/0312896 A1
(43) Pub. Date: Sep. 19, 2024

(54) SEMICONDUCTOR DEVICE

(71) Applicant: ROHM CO., LTD., Kyoto-shi (JP)

(72) Inventor: Natsuya YOSHIDA, Kyoto-shi (JP)

(21) Appl. No.: 18/675,646

(22) Filed: May 28, 2024

Related U.S. Application Data
(63) Continuation of application No. PCT/JP2022/043738, filed on Nov. 28, 2022.

(30) Foreign Application Priority Data
Dec. 10, 2021 (JP) 2021-200693

(51) Int. Cl. H01L 23/498; H01L 23/00

(52) U.S. Cl. CPC H01L 23/49838; H01L 23/49894; H01L 24/32; H01L 24/40; H01L 24/73; H01L 2224/32258; H01L 2224/40245; H01L 2224/73263; H01L 2924/182

(57) ABSTRACT

A semiconductor device includes a lead, semiconductor element, sealing resin and insulating substrate. The lead includes a die pad having first obverse and reverse surfaces opposite from each other in a thickness direction. The semiconductor element is fixed to the first obverse surface. The sealing resin covers the die pad and the semiconductor element. The insulating substrate includes a first metal layer, insulating layer and second metal layer stacked in this order. The insulating substrate includes second obverse and reverse surfaces respectively facing the same sides as the first obverse and reverse surfaces in the thickness direction. The first reverse surface and the second obverse surface are mutually fixed. The sealing resin includes an obverse surface and reverse surface respectively facing the same sides as the first obverse and reverse surfaces in the thickness direction. The second reverse surface is exposed from the reverse surface of the sealing resin.

### TECHNICAL FIELD

The present disclosure relates to semiconductor devices.

### BACKGROUND ART

JP-A-2017-174951 discloses an example of a semiconductor device that includes a first lead including a first pad having a pad obverse surface and a pad reverse surface, a semiconductor element mounted on the pad obverse surface, and a sealing resin in contact with the pad obverse surface and covering the semiconductor element. The semiconductor element is electrically bonded to the first pad via a bonding layer. When the semiconductor device is attached to a heat sink, an insulating sheet, for example, is placed between the pad reverse surface and the heat sink.

### BRIEF DESCRIPTION OF THE DRAWINGS

FIG. 1 is a perspective view of a semiconductor device according to a first embodiment of the present disclosure.

FIG. 2 is a plan view of the semiconductor device according to the first embodiment of the present disclosure.

FIG. 3 is a fragmentary plan view of the semiconductor device according to the first embodiment of the present disclosure.

FIG. 4 is a bottom view of the semiconductor device according to the first embodiment of the present disclosure.

FIG. 5 is a front view of the semiconductor device according to the first embodiment of the present disclosure.

FIG. 6 is a fragmentary sectional view taken along line VI-VI in FIG. 3.

FIG. 7 is a fragmentary sectional view taken along line VII-VII in FIG. 3.

FIG. 8 is an enlarged fragmentary plan view of the semiconductor device according to the first embodiment of the present disclosure.

FIG. 9 is an enlarged fragmentary sectional view of the semiconductor device according to the first embodiment of the present disclosure.

FIG. 10 is an enlarged fragmentary sectional view of the semiconductor device according to the first embodiment of the present disclosure.

FIG. 11 is a sectional view of a semiconductor device mount structure according to the first embodiment of the present disclosure.

FIG. 12 is a sectional view illustrating a method for manufacturing a semiconductor device according to the first embodiment of the present disclosure.

FIG. 13 is an enlarged fragmentary sectional view illustrating the method for manufacturing a semiconductor device according to the first embodiment of the present disclosure.

FIG. 14 is an enlarged fragmentary sectional view illustrating the method for manufacturing a semiconductor device according to the first embodiment of the present disclosure.

FIG. 15 is a perspective view of a semiconductor device according to a first variation of the first embodiment of the present disclosure.

FIG. 16 is a plan view of the semiconductor device according to the first variation of the first embodiment of the present disclosure.

FIG. 17 is a fragmentary plan view of the semiconductor device according to the first variation of the first embodiment of the present disclosure.

FIG. 18 is a bottom view of the semiconductor device according to the first variation of the first embodiment of the present disclosure.

FIG. 19 is a fragmentary sectional view taken along line XIX-XIX in FIG. 17.

FIG. 20 is a fragmentary sectional view of a semiconductor device according to a second embodiment of the present disclosure.

FIG. 21 is an enlarged fragmentary sectional view of the semiconductor device according to the second embodiment of the present disclosure.

FIG. 22 is an enlarged fragmentary sectional view of the semiconductor device according to the second embodiment of the present disclosure.

FIG. 23 is a fragmentary sectional view of a semiconductor device according to a third embodiment of the present disclosure.

FIG. 24 is a fragmentary sectional view illustrating a method for manufacturing a semiconductor device according to the third embodiment of the present disclosure.

### DETAILED DESCRIPTION OF EMBODIMENTS

Hereinafter, preferred embodiments of the present disclosure will be specifically described with reference to the drawings.

In the present disclosure, the terms such as “first”, “second”, “third”, and so on are used merely as labels to identify the items referred to by the terms and are not intended to impose a specific order or sequence on these items.

### First Embodiment

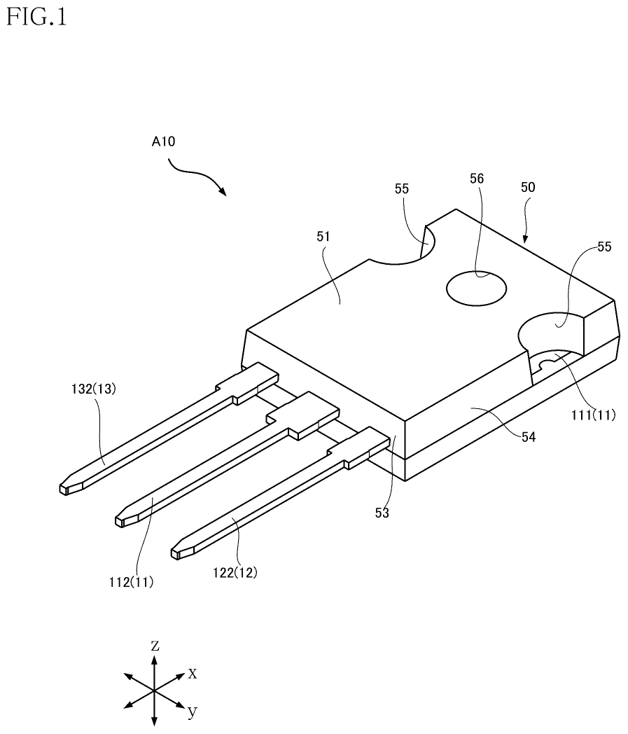

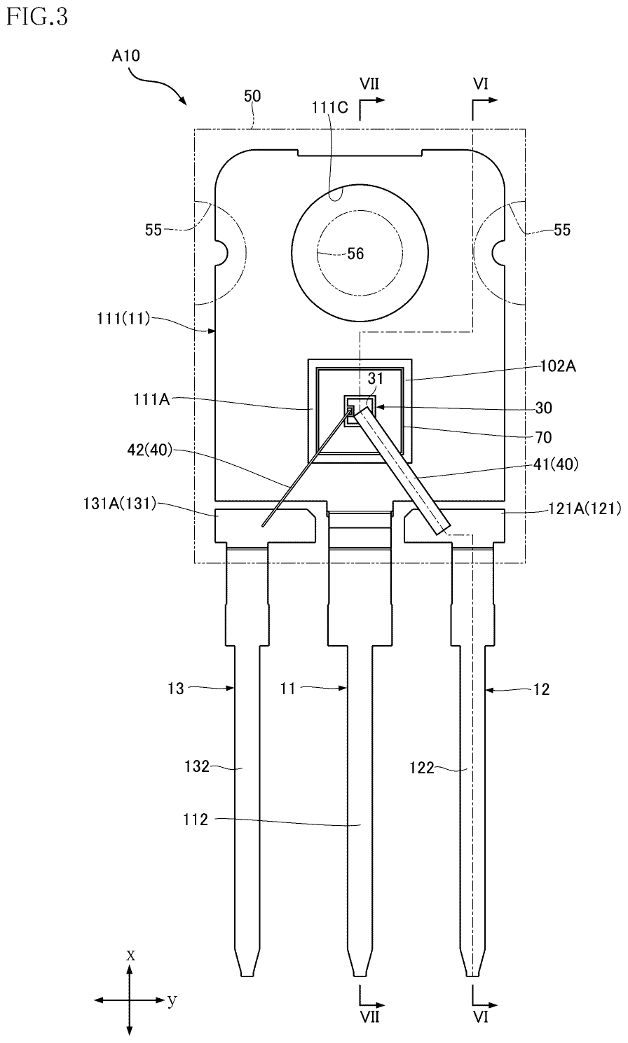

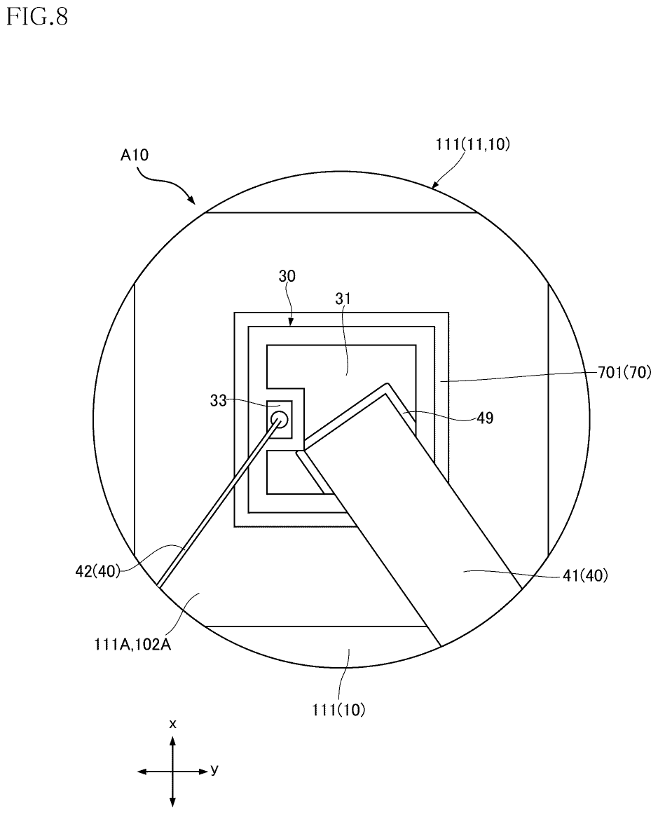

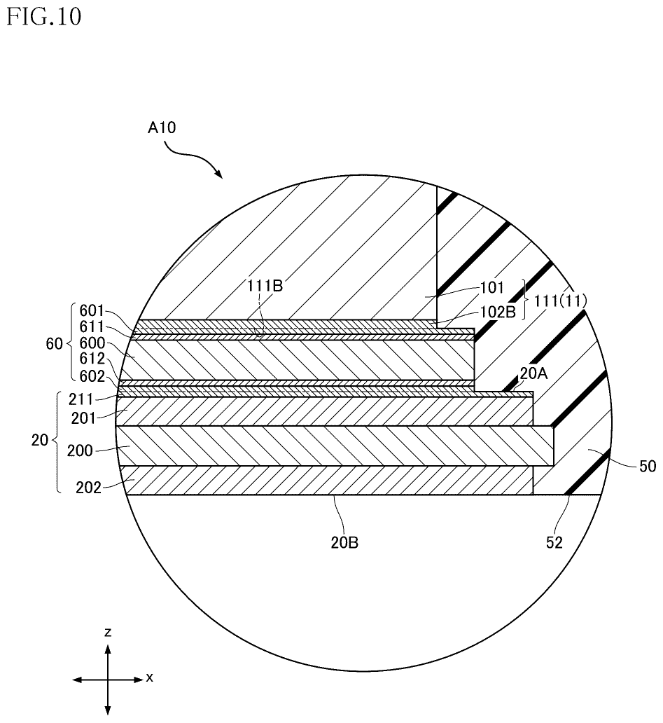

With reference to FIGS. 1 to 14, the following describes a semiconductor device A10 and a semiconductor device mount structure B10 according to a first embodiment of the present disclosure. The semiconductor device A10 can be used in an electronic device, such as a DC-DC converter, provided with a conversion circuit, for example. The semiconductor device A10 includes a first lead 11, a second lead 12, a third lead 13, a semiconductor element 30, a plurality of conductive members 40, an insulating substrate 20, a first bonding member 60, a second bonding member 70, and a sealing resin 50. For convenience of description, FIGS. 3 and 8 show the sealing resin 50 as transparent. In FIG. 3, the outline of the sealing resin 50 is indicated by an imaginary line (two-dot-dash line).

In the description of the semiconductor device A10, the z direction is an example of a “thickness direction”. A direction orthogonal to the z direction is referred to as an “x direction”, for example. The direction orthogonal to both the z direction and the x direction is referred to as a “y direction”, for example.

### First Lead 11

As shown in FIGS. 3, 4, 6, and 7, the first lead 11 includes a die pad portion 111 and a terminal portion 112. The first lead 11 is a conductive member on which where the semiconductor element 30 is mounted and forms a part of the conduction path between the semiconductor element 30 and a wiring board (not shown) when the semiconductor device A10 is mounted on the wiring board. The first lead 11 is an example of a “lead”.

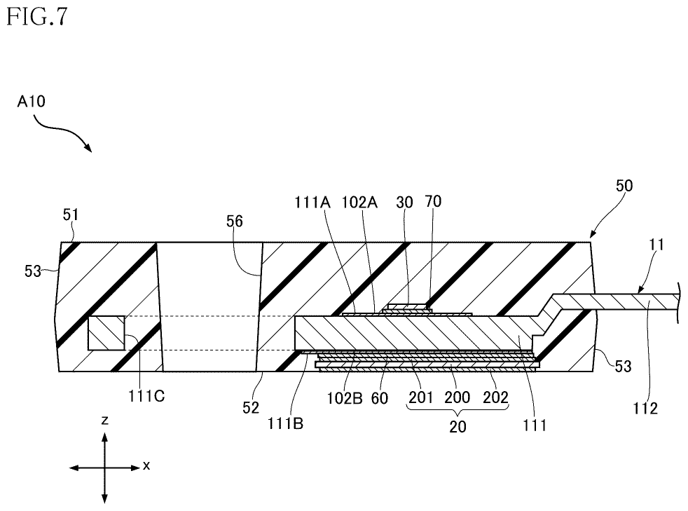

As shown in FIGS. 6 and 7, the first lead 11 includes a substrate 101, a first-obverse-surface metal layer 102A, and a first-reverse-surface metal layer 102B. The substrate 101 is the foundation of the first lead 11 and made of, for example, copper (Cu) or a copper alloy. That is, the composition of the substrate 101 includes copper. The first-obverse-surface metal layer 102A is deposited on one side of the substrate 101, covering the region forming the die pad portion 111. The first-reverse-surface metal layer 102B is deposited on one side of the substrate 101, covering the region forming the die pad portion 111. The first-obverse-surface metal layer 102A and the first-reverse-surface metal layer 102B are thinner than the substrate 101. The composition of each of the first-obverse-surface metal layer 102A and the first-reverse-surface metal layer 102B includes silver (Ag).

The die pad portion 111 includes the substrate 101, the first-obverse-surface metal layer 102A, and the first-reverse-surface metal layer 102B. The die pad portion 111 has a first obverse surface 111A, a first reverse surface 111B, and a through-hole 111C. In the present embodiment, the first obverse surface 111A is formed by a portion of the substrate 101 and the first-obverse-surface metal layer 102A. The first reverse surface 111B faces away from the first obverse surface 111A in the z direction. In the present embodiment, the first reverse surface 111B is formed by a portion of the substrate 101 and the first-reverse-surface metal layer 102B. The through-hole 111C penetrates the die pad portion 111 in the z direction. As viewed in the z direction, the through-hole 111C is circular.

As shown in FIGS. 3 and 7, the terminal portion 112 has a portion extending in the x direction and is connected to the substrate 101 of the die pad portion 111. Thus, the die pad portion 111 and the terminal portion 112 are electrically connected to each other. A portion of the terminal portion 112 is covered with the sealing resin 50. The terminal portion 112 has a bend as viewed in the y direction in the portion covered with the sealing resin 50. The surfaces of the terminal portion 112 that are exposed from the sealing resin 50 may be plated with tin (Sn), for example.

### Second Lead 12

As shown in FIG. 3, the second lead 12 is spaced apart from the first lead 11 and is electrically connected to the semiconductor element 30 via a conductive member 40. The second lead 12 includes a wire pad portion 121 and a terminal portion 122. The wire pad portion 121 is covered with the sealing resin 50 and has a second obverse surface 121A. The second obverse surface 121A faces the same side as the first obverse surface 111A in the z direction. The second obverse surface 121A may be plated with silver (Ag), tin (Sn), or the like. The terminal portion 122 is connected to the wire pad portion 121. The terminal portion 122 has a portion covered with the sealing resin 50 and a portion exposed from the sealing resin 50. The terminal portion 122 extends in the x direction, parallel to the terminal portion 112, for example. The surfaces of the terminal portion 122 may be plated with tin (Sn), for example.

### Third Lead 13

As shown in FIG. 3, the third lead 13 is spaced apart from the first lead 11 on the side opposite to the second lead 12 in the y direction. The third lead 13 is electrically connected to the semiconductor element 30 via a conductive member 40. The third lead 13 includes a wire pad portion 131 and a terminal portion 132. The wire pad portion 131 is covered with the sealing resin 50 and has a second obverse surface 131A. The second obverse surface 131A faces the same side as the first obverse surface 111A in the z direction. The second obverse surface 131A may be plated with silver (Ag), tin (Sn), or the like. The terminal portion 132 is connected to the wire pad portion 131. The terminal portion 132 has a portion covered with the sealing resin 50 and a portion exposed from the sealing resin 50. The terminal portion 132 extends in the x direction, parallel to the terminal portion 112, for example. The surfaces of the terminal portion 132 may be plated with tin (Sn), for example.

### Semiconductor Element 30

As shown in FIGS. 3, 6, and 7, the semiconductor element 30 is fixed to the first obverse surface 111A of the die pad portion 111 and hence is located on the side of the first obverse surface 111A of the die pad portion 111 of the first lead 11. For the semiconductor device A10, the semiconductor element 30 is an n-channel, vertical metal-oxide-semiconductor field-effect transistor (MOSFET). The semiconductor element 30 is not limited to an MOSFET. The semiconductor element 30 may be a different type of transistor, such as an insulated gate bipolar transistor (IGBT). Alternatively, the semiconductor element 30 may be an LSI or a diode. The semiconductor element 30 includes a semiconductor layer 35, a first electrode 31, a second electrode 32, and a third electrode 33.

The semiconductor layer 35 includes a compound semiconductor substrate. The compound semiconductor substrate is mainly composed of silicon carbide (Sic). In another example, the main component of the semiconductor substrate may be silicon (Si).

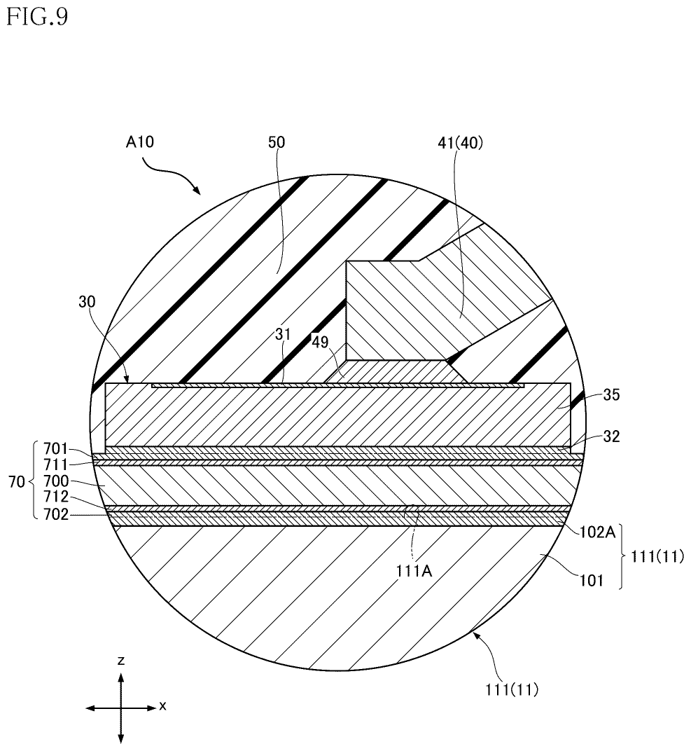

As shown in FIGS. 8 and 9, the first electrode 31 is disposed on the side facing the same side in the z direction as the first obverse surface 111A of the die pad portion 111 of the first lead 11. The first electrode 31 carries the current corresponding to the power converted by the semiconductor element 30. That is, the first electrode 31 corresponds to the source electrode of the semiconductor element 30.

As shown in FIG. 9, the second electrode 32 is disposed on the side opposite to the first electrode 31 in the z direction. The second electrode 32 faces the first obverse surface 111A of the die pad portion 111 of the first lead 11. The second electrode 32 is an example of a “reverse-surface metal layer”. The second electrode 32 carries the current corresponding to the power to be converted by the semiconductor element 30. That is, the second electrode 32 corresponds to the drain electrode of the semiconductor element 30. In the present embodiment, at least the surface layer of the second electrode 32 contains silver (Ag).

As shown in FIG. 8, the third electrode 33 is disposed on the same side as the first electrode 31 in the z direction and spaced apart from the first electrode 31. The third electrode 33 receives a gate voltage applied for driving the semiconductor element 30. That is, the third electrode 33 corresponds to the gate electrode of the semiconductor element 30. As viewed in the z direction, the third electrode 33 is larger in area than the first electrode 31.

The second lead 12 is electrically connected to the first electrode 31 of the semiconductor element 30. The terminal portion 122 thus corresponds to the source terminal of the semiconductor device A10. The third lead 13 is electrically connected to the third electrode 33 of the semiconductor element 30. The terminal portion 132 thus corresponds to the gate terminal of the semiconductor device A10.

### Insulating Substrate 20

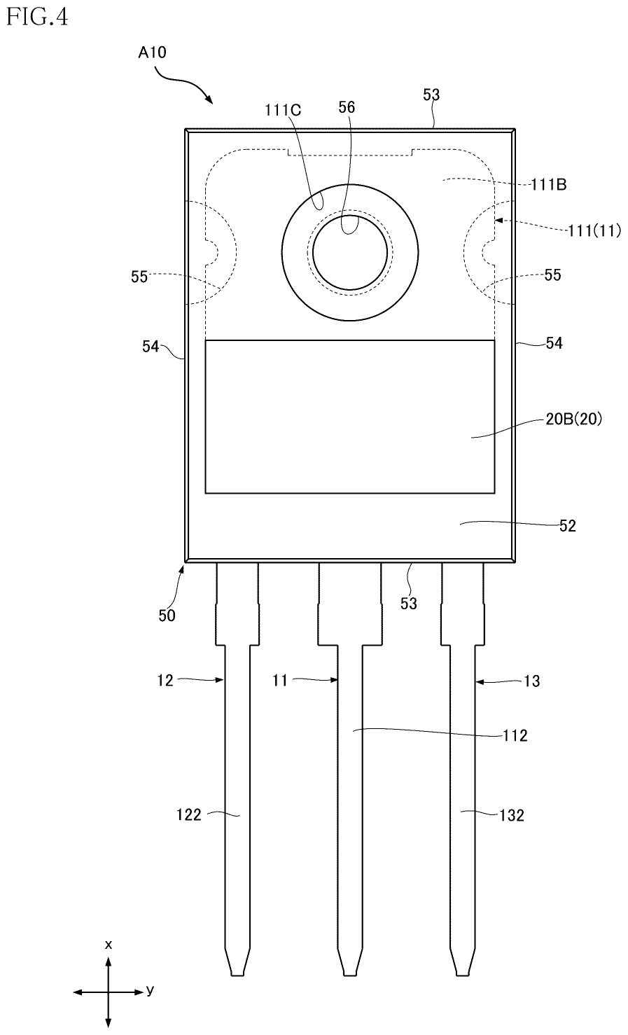

The insulating substrate 20 is fixed to the first reverse surface 111B of the die pad portion 111. As shown in FIGS. 4, 6, 7, and 10, the insulating substrate 20 includes an insulating layer 200, a first substrate metal layer 201, and a second substrate metal layer 202. In the z direction, the first substrate metal layer 201, the insulating layer 200, and the second substrate metal layer 202 are stacked in the stated order from the top to the bottom as seen in the figure. The insulating substrate 20 has a second obverse surface 20A and a second reverse surface 20B. The second obverse surface 20A faces the same side as the first obverse surface 111A in the z direction. The second reverse surface 20B faces the same side as the first reverse surface 111B in the z direction.

The insulating substrate 20 may have a thickness of 500 to 1300 μm, for example.

The insulating layer 200 is a plate containing an The insulating layer 200 may contain a insulating material. ceramic material, such as Al 03, SiN, or AlN. The insulating layer 200 may have a thickness of 300 to 500 μm, for example. The first substrate metal layer 201 is deposited on one side of the insulating layer 200. The first substrate metal layer 201 is made of metal, examples of which include copper (Cu).

The first substrate metal layer 201 may have a thickness of 100 to 500 μm, for example. The second substrate metal layer 202 is deposited on one side of the insulating layer 200. The second substrate metal layer 202 is made of metal, examples of which include copper (Cu). The second substrate metal layer 202 may have a thickness of 100 to 500 μm, for example. In the present embodiment, the insulating substrate 20 additionally includes a second-obverse-surface metal layer 211. The second-obverse-surface metal layer 211 is deposited on the first substrate metal layer 201. The second-obverse-surface metal layer 211 is a plating layer of silver (Ag), for example. In the present embodiment, the second obverse surface 20A is formed by the second-obverse-surface metal layer 211, and the second reverse surface 20B is formed by the second substrate metal layer 202.

As shown in FIGS. 4 and 7, the insulating substrate 20 is disposed at a location not overlapping with the through-hole 111C as viewed in the z direction and spaced apart from the through-hole 111C. As viewed in the z direction, the insulating substrate 20 is smaller than the die pad portion 111. As viewed in the z direction, in addition, the insulating substrate 20 overlaps with the semiconductor element 30, and more specifically with the entirety of the semiconductor element 30.

### First Bonding Member 60

As shown in FIGS. 6, 7, and 10, the first bonding member 60 is interposed between the die pad portion 111 of the first lead 11 and the insulating substrate 20. The first bonding member 60 of the present embodiment includes a first base metal layer 600, a first bonding metal layer 601, a second bonding metal layer 602, a first intermediate metal layer 611, and a second intermediate metal layer 612. The first bonding member 60 may have a thickness of 50 to 400 μm, for example. The first base metal layer 600 is the foundation of the first bonding member 60. The material of the first base metal layer 600 is not limited and may include Al in the present embodiment.

The first bonding metal layer 601 is disposed on the side toward the die pad portion 111 with respect to the first base metal layer 600. The first bonding metal layer 601 is a layer that is joined to the first-reverse-surface metal layer 102B of the die pad portion 111. In the present embodiment, the first bonding metal layer 601 contains silver (Ag) and is joined to the first-reverse-surface metal layer 102B by solid-state diffusion bonding. After solid-state diffusion bonding, the boundary between the first bonding metal layer 601 and the first-reverse-surface metal layer 102B typically becomes less distinct. In the figure, the boundary is thus represented by an imaginary line. The boundary between the first bonding metal layer 601 and the first-reverse-surface metal layer 102B becomes less distinct because metal grains form at the boundary. However, if there is an excessively large gap or an excessive amount of contaminants between the first bonding metal layer 601 and the first-reverse-surface metal layer 102B, the gap or contaminants may persist, and the boundary may remain distinct. The first reverse surface 111B of the die pad portion 111 thus includes a portion that may not appear as a distinct surface.

The second bonding metal layer 602 is disposed on the side opposite to the die pad portion 111 with respect to the first base metal layer 600. The second bonding metal layer 602 is a layer that is joined to the second-obverse-surface metal layer 211 of the insulating substrate 20. In the present embodiment, the second bonding metal layer 602 contains silver (Ag) and is joined to the second-obverse-surface metal layer 211 by solid-state diffusion bonding. After solid-state diffusion bonding, the boundary between the second bonding metal layer 602 and the second-obverse-surface metal layer 211 typically becomes less distinct. In the figure, the boundary is thus represented by an imaginary line. The boundary between the second bonding metal layer 602 and the second-obverse-surface metal layer 211 becomes less distinct because metal grains form at the boundary. However, if there is an excessively large gap or an excessive amount of contaminants between the second bonding metal layer 602 and the second-obverse-surface metal layer 211, the gap or contaminants may persist, and the boundary may remain distinct. The second obverse surface 20A of the insulating substrate 20 thus includes a portion that may not appear as a distinct surface.

The first intermediate metal layer 611 is interposed between the first base metal layer 600 and the first bonding metal layer 601. The first intermediate metal layer 611 contains nickel (Ni), for example. The second intermediate metal layer 612 is interposed between the first base metal layer 600 and the second bonding metal layer 602. The second intermediate metal layer 612 contains nickel (Ni), for example.

### Second Bonding Member 70

As shown in FIGS. 6, 7, and 9, the second bonding member 70 is interposed between the semiconductor element 30 and the first lead 11 of the die pad portion 111. The second bonding member 70 of the present embodiment includes a second base metal layer 700, a third bonding metal layer 701, a fourth bonding metal layer 702, a third intermediate metal layer 711, and a fourth intermediate metal layer 712. The second bonding member 70 may have a thickness of 50 to 400 μm, for example.

The second base metal layer 700 is the foundation of the second bonding member 70. The material of the second base metal layer 700 is not limited and includes Al in the present embodiment.

The third bonding metal layer 701 is disposed on the side toward the semiconductor element 30 with respect to the second base metal layer 700. The third bonding metal layer 701 is a layer that is joined to the second electrode 32 of the semiconductor element 30. In the present embodiment, the third bonding metal layer 701 contains silver (Ag) and is joined to the second electrode 32 by solid-state diffusion bonding. After solid-state diffusion bonding, the boundary between the third bonding metal layer 701 and the second electrode 32 typically becomes less distinct. In the figure, the boundary is thus represented by an imaginary line. The boundary between the third bonding metal layer 701 and the second electrode 32 becomes less distinct because metal grains form at the boundary. However, if there is an excessively large gap or an excessive amount of contaminants between the third bonding metal layer 701 and the second electrode 32, the gap or contaminants may persist, and the boundary may remain distinct.

The fourth bonding metal layer 702 is disposed on the side toward the die pad portion 111 with respect to the second base metal layer 700. The fourth bonding metal layer 702 is a layer that is joined to the first-obverse-surface metal layer 102A of the die pad portion 111. In the present embodiment, the fourth bonding metal layer 702 contains silver (Ag) and is joined to the first-obverse-surface metal layer 102A by solid-state diffusion bonding. After solid-state diffusion bonding, the boundary between the fourth bonding metal layer 702 and the first-obverse-surface metal layer 102A typically becomes less distinct. In the figure, the boundary is thus represented by an imaginary line. The boundary between the fourth bonding metal layer 702 and the first-obverse-surface metal layer 102A becomes less distinct because metal grains form at the boundary. However, if there is an excessively large gap or an excessive amount of contaminants between the fourth bonding metal layer 702 and the first-obverse-surface metal layer 102A, the gap or contaminants may persist, and the boundary may remain distinct. The first obverse surface 111A of the die pad portion 111 thus includes a portion that may not appear as a distinct surface.

The third intermediate metal layer 711 is interposed between the second base metal layer 700 and the third bonding metal layer 701. The third intermediate metal layer 711 contains nickel (Ni), for example. The fourth intermediate metal layer 712 is interposed between the second base metal layer 700 and the fourth bonding metal layer 702. The fourth intermediate metal layer 712 contains nickel (Ni), for example.

### Conductive Members 40

As shown in FIG. 3, the conductive members 40 are electrically bonded to the semiconductor element 30 and the second and third leads 12 and 13. This provides electrical interconnection between the semiconductor element 30 and the second and third leads 12 and 13. The conductive members 40 include a first member 41 and a second member 42.

As shown in FIGS. 3, 8, and 9, the first member 41 is electrically bonded to the first electrode 31 of the semiconductor element 30 and the second obverse surface 121A of the wire pad portion 121 of the second lead 12. This electrically connects the second lead 12 to the first electrode 31. The composition of the first member 41 includes copper. For the semiconductor device A10, the first member 41 is a metal clip. The first member 41 is electrically bonded to the first electrode 31 and the wire pad portion 121 via a second bonding layer 49. The second bonding layer 49 contains a metallic element. The metallic element may be tin (Sn), for example. The second bonding layer 49 may be solder, for example. In another example, the first member 41 may be a wire. In this case, the first member 41 is formed by wire bonding, so that the second bonding layer 49 is not necessary.

As shown in FIGS. 3 and 8, the second member 42 is electrically bonded to the third electrode 33 of the semiconductor element 30 and the second obverse surface 131A of the wire pad portion 131 of the third lead 13. This electrically connects the third lead 13 to the third electrode 33. The second member 42 is a wire. The second member 42 is formed by wire bonding. The composition of the second member 42 includes Al.

### Sealing Resin 50

As shown in FIGS. 1 to 7, the sealing resin 50 covers the semiconductor element 30, the conductive members 40, the first bonding member 60, and the second bonding member 70, and portions of each of the first lead 11, the second lead 12, the third lead 13, and the insulating substrate 20. The sealing resin 50 is electrically insulating. The sealing resin 50 is made of a material containing a black epoxy resin, for example. The sealing resin 50 has a resin obverse surface 51, a resin reverse surface 52, a pair of first side surfaces 53, a pair of second side surfaces 54, a pair of openings 55, and a mounting hole 56.

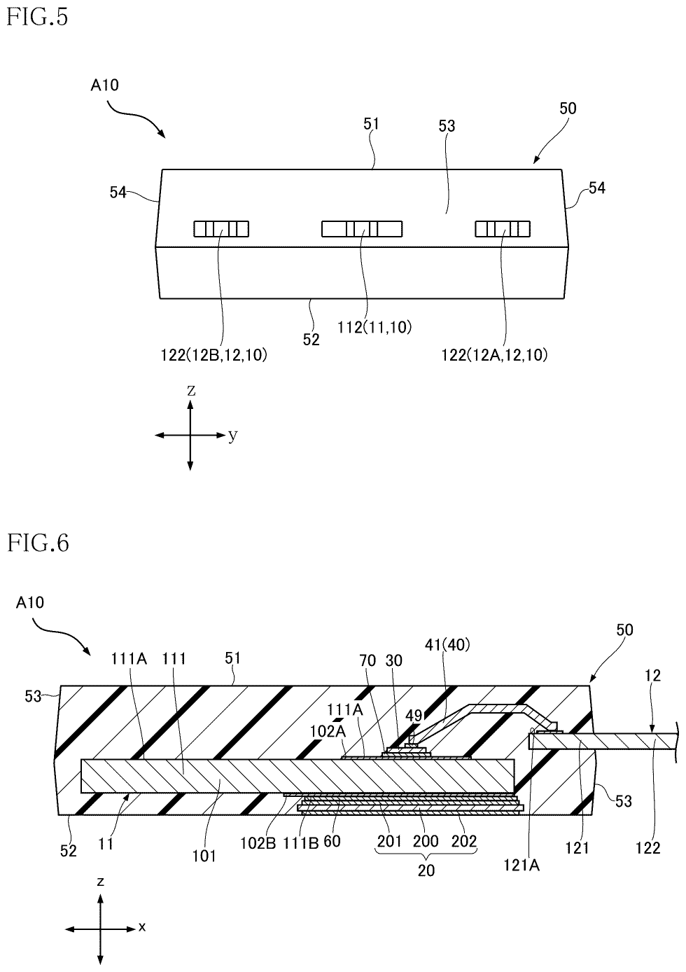

As shown in FIGS. 6 and 7, the resin obverse surface 51 faces the same side as the first obverse surface 111A of the die pad portion 111 of the first lead 11 in the z direction. As shown in FIGS. 5 to 7, the resin reverse surface 52 faces away from the resin obverse surface 51 in the z direction. As shown in FIGS. 4, 6 and 7, the second reverse surface 20B of the insulating substrate 20 is exposed from the resin reverse surface 52. The second reverse surface 20B and the resin reverse surface 52 are flush with each other.

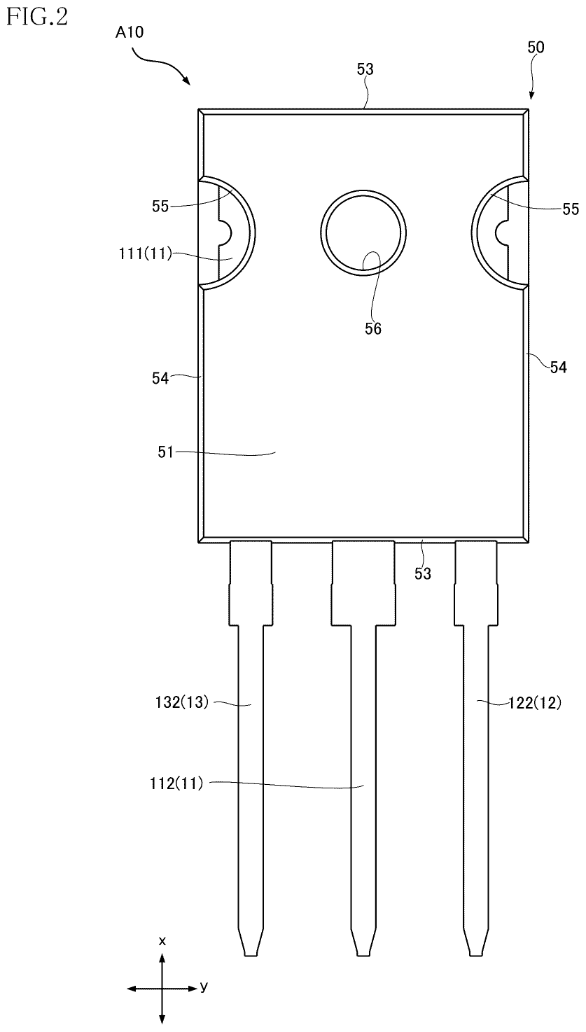

As shown in FIGS. 2 and 4, the first side surfaces 53 are spaced apart from each other in the x direction. The first side surfaces 53 are connected to the resin obverse surface 51 and the resin reverse surface 52. As shown in FIG. 5, one of the first side surfaces 53 exposes the terminal portion 112 of the first lead 11, the terminal portion 122 of the second lead 12, and the terminal portion 132 of the third lead 13.

As shown in FIGS. 2, 4, and 5, the second side surfaces 54 are spaced apart from each other in the y direction. The second side surfaces 54 are connected to the resin obverse surface 51 and the resin reverse surface 52. As shown in FIG. 2, the openings 55 are spaced apart from each other in the y direction. Each opening 55 is recessed inwardly of the sealing resin 50 from the resin obverse surface 51 and one of the second side surfaces 54. Each opening 55 exposes a portion of the first obverse surface 111A of the die pad portion 111 of the first lead 11. As shown in FIGS. 2, 4, and 7, the mounting hole 56 penetrates the sealing resin 50 in the z direction, extending from the resin obverse surface 51 to the resin reverse surface 52. As viewed in the z direction, the mounting hole 56 is contained within the through-hole 111C of the die pad portion 111 of the first lead 11. The inner peripheral surface of the die pad portion 111, which defines the through-hole 111C, is covered with the sealing resin 50. Hence, the maximum dimension of the mounting hole 56 is smaller than the dimension of the through-hole 111C as viewed in the z direction.

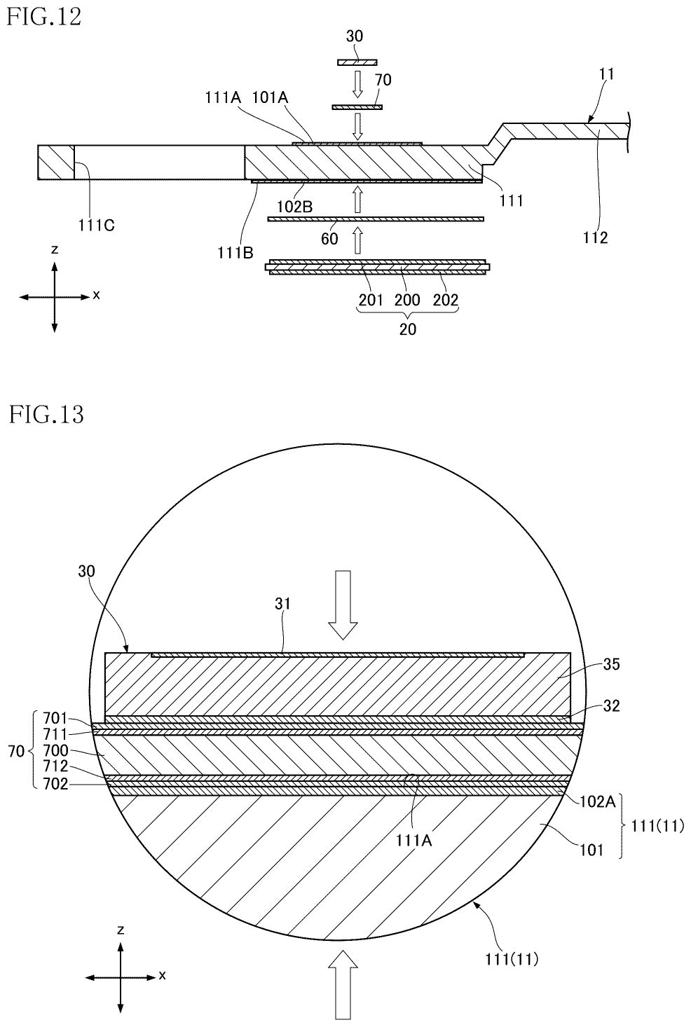

FIGS. 12 to 14 illustrate an example of a method for manufacturing the semiconductor device A10. This method uses solid-state diffusion bonding to join the die pad portion 111 of the first lead 11, the first bonding member 60, the insulating substrate 20, the second bonding member 70, and the semiconductor element 30. The bonding process may be performed collectively for the components to be joined or separately for each pair of components to be joined. Solid-state diffusion bonding can join two metal layers together by placing the metal layers in close contact with each other and applying a pressure to the extent not causing plastic deformation, while the temperature is maintained below the melting points of the metal layers. This causes atomic diffusion at the interface, resulting in the bonding of the metal layers.

As shown in FIG. 13, the semiconductor element 30 and the second bonding member 70 are joined together by solid-state diffusion bonding of the second electrode 32 and the third bonding metal layer 701. The second bonding member 70 and the die pad portion 111 are joined together by solid-state diffusion bonding of the fourth intermediate metal layer 712 and the first-obverse-surface metal layer 102A.

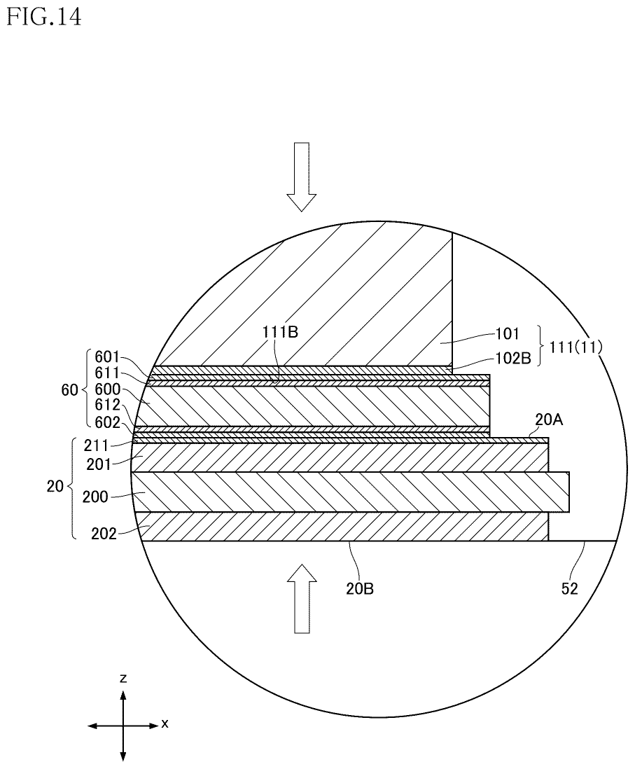

As shown in FIG. 14, the die pad portion 111 and the first bonding member 60 are joined together by solid-state diffusion bonding of the first-reverse-surface metal layer 102B and the first bonding metal layer 601. The first bonding member 60 and the insulating substrate 20 are joined together by solid-state diffusion bonding of the second bonding metal layer 602 and the second-obverse-surface metal layer 211.

### Semiconductor Device Mount structure B10

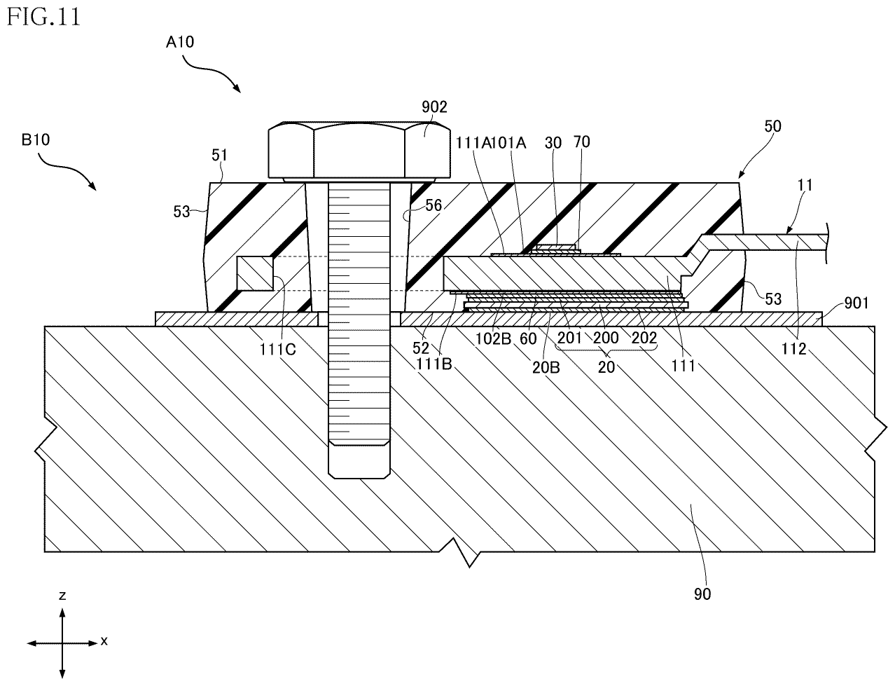

FIG. 11 shows a semiconductor device mount structure B10 according to the present embodiment. The semiconductor device mount structure B10 includes the semiconductor device A10, a heat sink 90, and a sheet material 901.

The heat sink 90 is a component that receives heat generated by the semiconductor device A10. The heat sink 90 is typically made of metal, including Al, for example.

The sheet material 901 is interposed between the semiconductor device A10 and the heat sink 90. The sheet material 901 preferably contains a material that is highly heat conductive, such as carbon. The sheet material 901 is in contact with the second reverse surface 20B of the insulating substrate 20 of the semiconductor device A10. The sheet material 901 is preferably softer than the second substrate metal layer 202 of the insulating substrate 20. In the illustrated example, the sheet material 901 is larger than the second reverse surface 20B of the insulating substrate 20 and also the semiconductor device A10, as viewed in the z direction.

In the present embodiment, the semiconductor device A10 is fixed to the heat sink 90 using a bolt 902. The bolt 902 is inserted through the mounting hole 56 of the semiconductor device A10 and threaded into an internally threaded hole of the heat sink 90.

The following describes the operation of the semiconductor device A10 and the semiconductor device mount structure B10.

The insulating substrate 20 is fixed to the first reverse surface 111B of the die pad portion 111 of the first lead 11. The insulating substrate 20 includes the insulating layer 200, the first substrate metal layer 201, and the second substrate The second reverse surface 20B of the metal layer 202. insulating substrate 20 is exposed from the resin reverse surface 52 of the sealing resin 50. The insulating layer 200 is covered with the sealing resin 50 and protected by the sealing resin 50. As a result, the insulating layer 200 is not easily affected by external forces and prevented from being damaged. Consequently, the thickness of the insulating layer 200 only needs to be sufficient to ensure the dielectric resistance required for, for example, the operation of the semiconductor element 30 and does not need to be sufficient to prevent potential damage from external forces. The semiconductor device A10 is therefore enabled to quickly release the heat generated by the semiconductor element 30 through the die pad portion 111 and the insulating substrate 20. That is, the semiconductor device A10 is improved in the efficiency of heat transfer to the outside.

The second reverse surface 20B is flush with the resin reverse surface 52. This means that the insulating layer 200 is completely covered with the sealing resin 50 and more reliably prevented from being exposed on the resin reverse surface 52. This is preferable for protecting the insulating layer 200 from damage. Additionally, because the second reverse surface 20B is flush with the resin reverse surface 52, the semiconductor device A10 can be more securely pressed against and fixed to the heat sink 90 via the sheet material 901.

The first reverse surface 111B of the die pad portion 111 and the second obverse surface 20A of the insulating substrate 20 are joined together by solid-state diffusion bonding via the first bonding member 60. Solid-state diffusion bonding is suitable for creating joints capable of preventing detachment or cracking under stress or the like.

The second electrode 32 of the semiconductor element 30 and the first obverse surface 111A of the die pad portion 111 are joined together by solid-state diffusion bonding via the second bonding member 70. Solid-state diffusion bonding is suitable for creating joints that prevent detachment or cracking under stress or the like.

In the semiconductor device A10, the die pad portion 111 and the second substrate metal layer 202 are insulated by the insulating layer 200. Thus, the semiconductor device mount structure B10 is not required to insulate the second substrate metal layer 202 and the heat sink 90 with the sheet material 901. This allows the sheet material 901 to be made of a conductive material, such as carbon. This helps to improve the efficiency of heat transfer from the semiconductor device A10 to the heat sink 90.

The sheet material 901 is softer than the second substrate metal layer 202 and is deformable to conform to the shape of the second substrate metal layer 202 (the second reverse surface 20B). This is preferable for preventing the formation of a gap between the second substrate metal layer 202 (the second reverse surface 20B) and the sheet material 901 and for improving the efficiency of heat transfer.

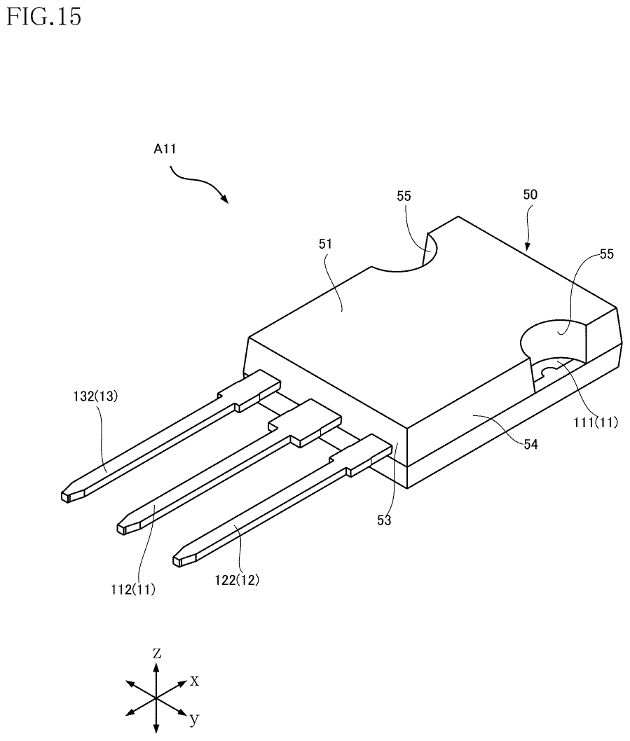

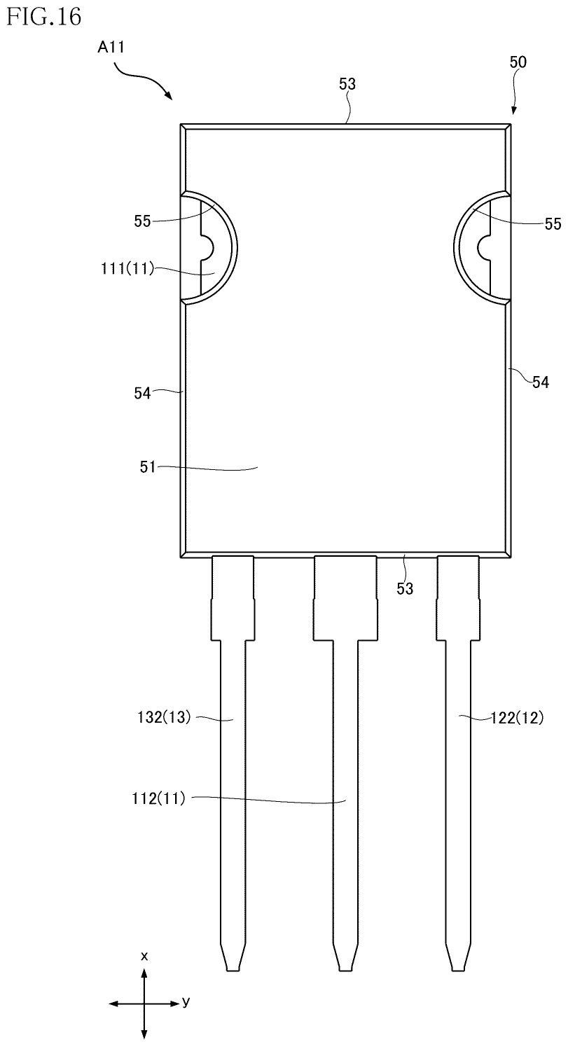

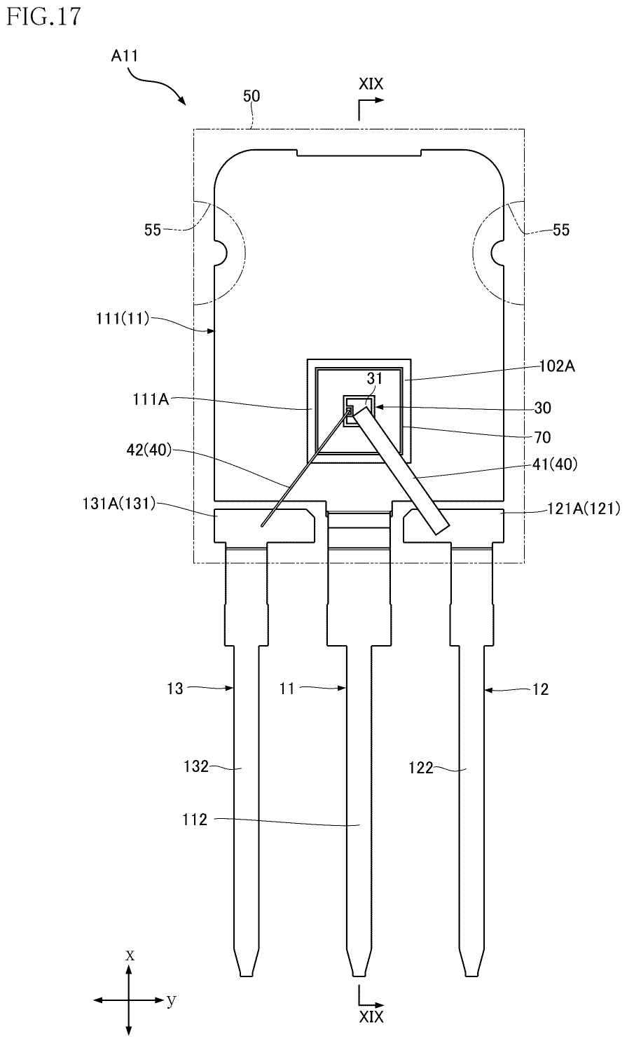

FIGS. 15 to 24 show variations and other embodiments of the present disclosure. In these figures, elements that are identical or similar to those described in the embodiment described above are indicated by the same reference numerals.

### First Variation of First Embodiment

FIGS. 15 to 19 show a semiconductor device A11 according to a first variation of the semiconductor device A10. In the semiconductor device A11, the die pad portion 111 of the first lead 11 does not have the through-hole 111C described above. Additionally, the sealing resin 50 does not have the mounting hole 56 described above. To attach the semiconductor device A11 to the heat sink 90 shown in FIG. 11, the sheet material 901 is placed between the heat sink 90 and the semiconductor device A11, and the resin obverse surface 51 of the semiconductor device A11 is pressed against the heat sink 90 in the z direction using a predetermined component (not illustrated). As a result, the semiconductor device A11 is fixed to the heat sink 90 via the sheet material 901, thus forming the semiconductor device mount structure of this variation.

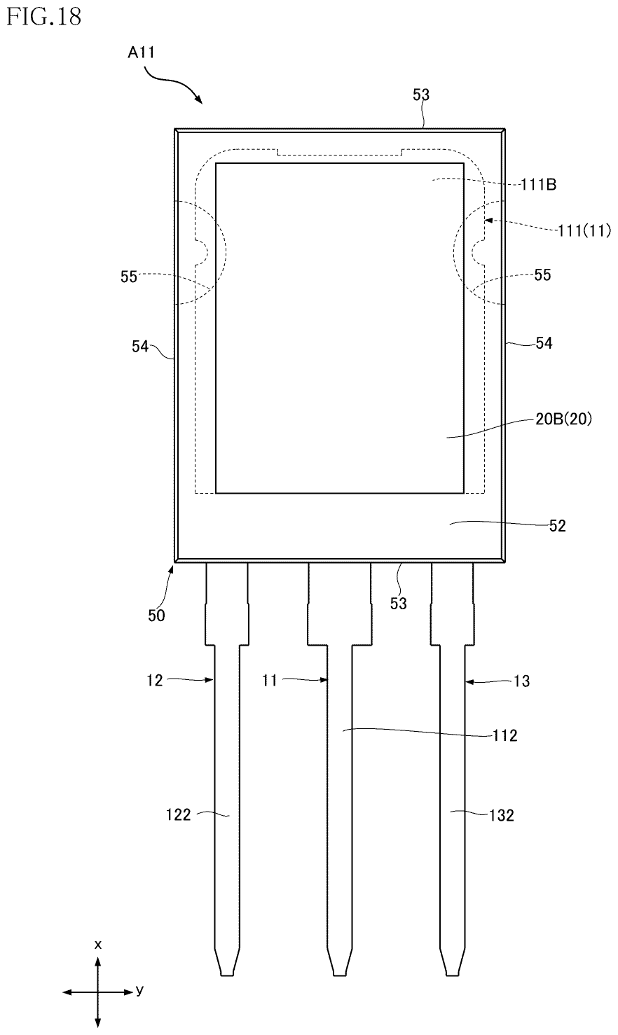

As shown in FIGS. 18 and 19, as viewed in the z direction, the insulating substrate 20 of this variation is clearly larger than the insulating substrate 20 of the semiconductor device A10 and almost as large as the die pad portion 111. This is because, unlike the insulating substrate 20 of the semiconductor device A10, the insulating substrate 20 of the semiconductor device A11 is not required to avoid interference with the bolt 902.

This variation helps to improve the efficiency of heat transfer from the semiconductor device A11 to the heat sink 90.

### Second Embodiment

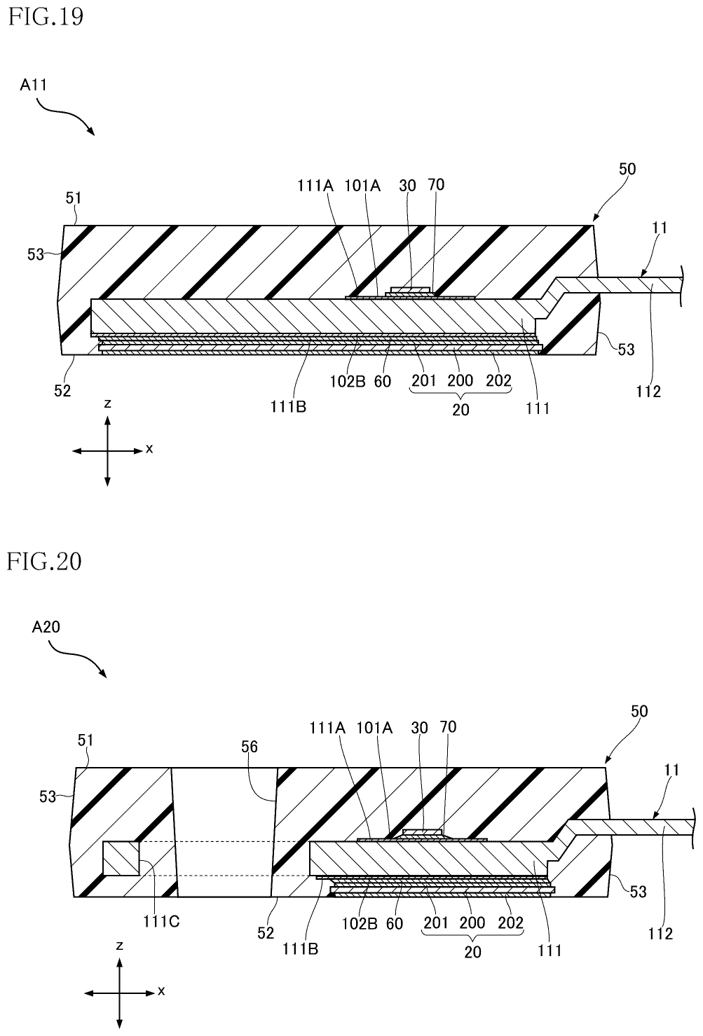

FIGS. 20 to 22 show a semiconductor device A20 according to a second embodiment of the present disclosure. The semiconductor device A20 of the present embodiment differs from the embodiment described above in the configuration of fixing the first reverse surface 111B of the die pad portion 111 of the first lead 11 and the second obverse surface 20A of the insulating 20. In addition, the substrate configuration of fixing the semiconductor element 30 and the first obverse surface 111A of the die pad portion 111 of the first lead 11 is also different.

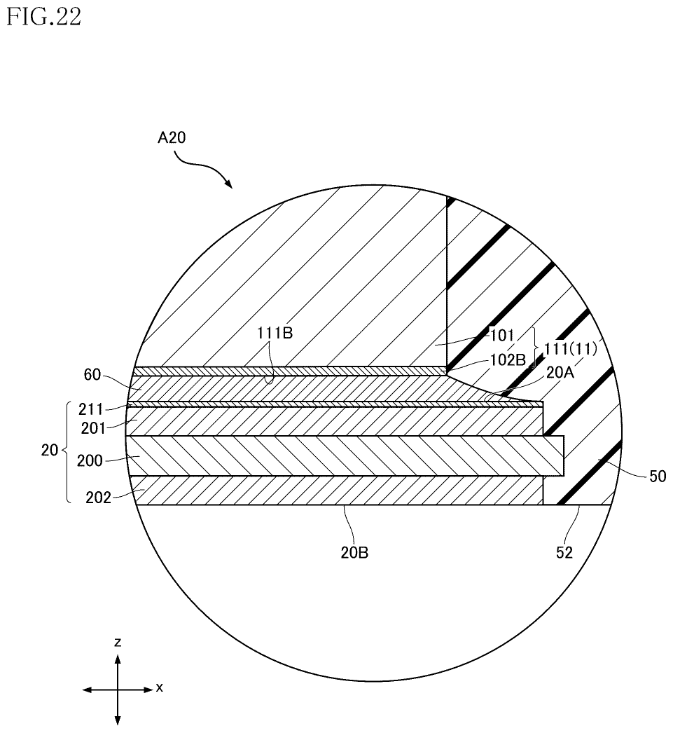

As shown in FIG. 22, the first bonding member 60 of the present embodiment is composed of a single layer and joined to the first-reverse-surface metal layer 102B (the first reverse surface 111B) and the second-obverse-surface metal layer 211 (the second obverse surface 20A). In this way, the first-reverse-surface metal layer 102B (the first reverse surface 111B) and the second-obverse-surface metal layer 211 (the second obverse surface 20A) are fixed to each other. The first bonding member 60 may be a sintered silver (Ag) layer or a solder layer, for example. The materials of the first-reverse-surface metal layer 102B and the second-obverse-surface metal layer 211 are appropriately selected based on the first bonding member 60. Additionally, the insulating substrate 20 may not include the second-obverse-surface metal layer 211. In this case, the first substrate metal layer 201 forms the second obverse surface 20A.

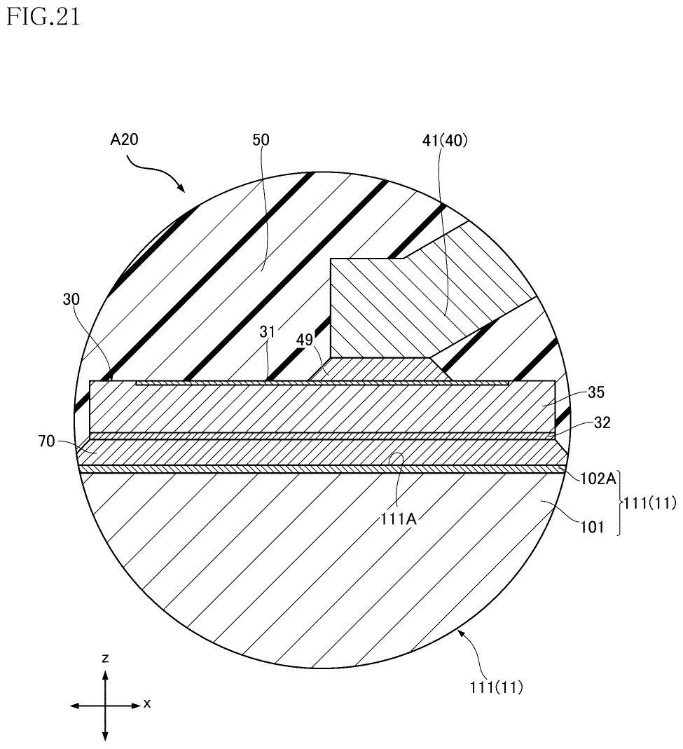

As shown in FIG. 21, the second bonding member 70 is composed of a single layer and joined to the second electrode 32 and the first-obverse-surface metal layer 102A (the first obverse surface 111A). In this way, the second electrode 32 and the first-obverse-surface metal layer 102A (the first obverse surface 111A) are fixed to each other. The second bonding member 70 may be a sintered silver (Ag) layer or of a solder layer, for example. The materials of the second electrode 32 and the first-obverse-surface metal layer 102A are appropriately selected based on the second bonding member 70.

The present embodiment helps to improve the efficiency of heat transfer from the semiconductor device A20 to the heat sink 90. As can be understood from the present embodiment, the configurations of the first bonding member 60 and the second bonding member 70 are not limited. The first bonding member 60 and the second bonding member 70 of the semiconductor device A10 and the first bonding member 60 and the second bonding member 70 of the semiconductor device A20 may be combined in many ways.

### Third Embodiment

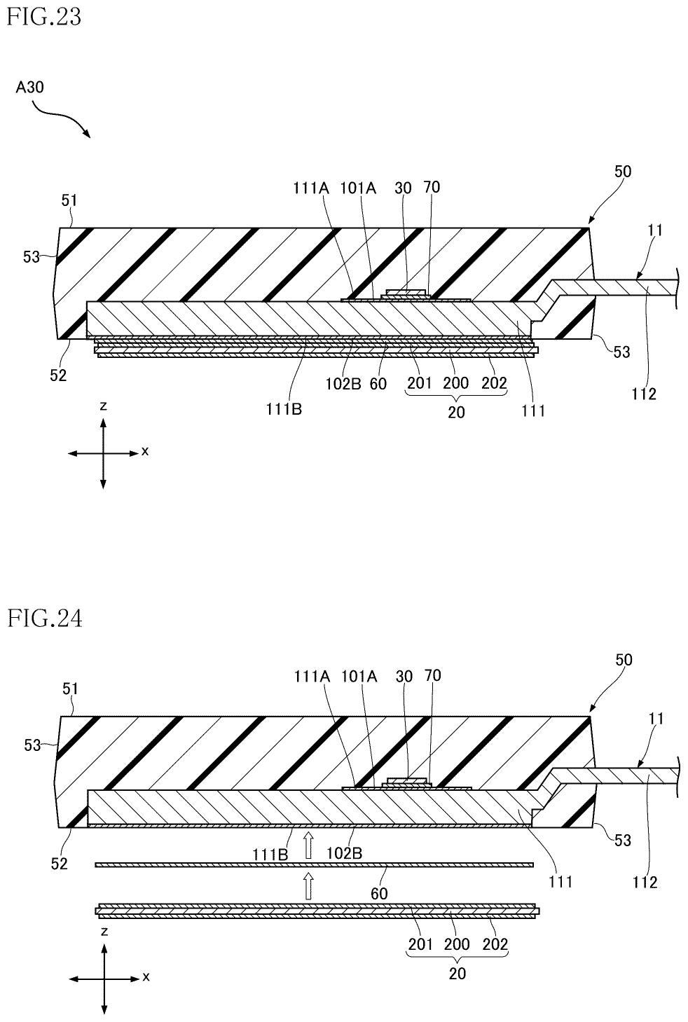

FIGS. 23 and 24 show a semiconductor device A30 according to a third embodiment of the present disclosure. For the semiconductor device A30 of the present embodiment, the first bonding member 60 and the insulating substrate 20 are exposed from the resin reverse surface 52 of the sealing resin 50. The first bonding member 60 and the insulating substrate 20 protrude in the z direction beyond the resin reverse surface 52. As to the configuration of fixing the first reverse surface 111B of the die pad portion 111 of the first lead 11 and the insulating substrate 20 via the first bonding member 60, the semiconductor device A30 is similar to the semiconductor device A10.

FIG. 24 shows a step of a method for manufacturing the semiconductor device A30. In the present embodiment, the semiconductor element 30 is mounted on the first obverse surface 111A of the die pad portion 111, the sealing resin 50 is formed, and then the insulating substrate 20 is fixed to the first reverse surface 111B via the first bonding member 60. As described for the semiconductor device A10, the fixing process involves joining the first reverse surface 111B and the first bonding member 60 and joining the first bonding member 60 and the insulating substrate 20 both by solid-state diffusion bonding.

The present embodiment helps to improve the efficiency of heat transfer from the semiconductor device A30 to the heat sink 90. As can be understood from the present embodiment, the relation of the first bonding member 60 and the insulating substrate 20 with the sealing resin 50 is not limited.

The semiconductor device and the semiconductor device mount structure according to the present disclosure are not limited to the embodiments described above. Various design changes can be made to the specific configuration of each part of the semiconductor device and the semiconductor device mount structure according to the present disclosure. The present disclosure includes the embodiments described in the following clauses.

Clause 1.

A semiconductor device comprising:
a lead including a die pad portion that includes a first obverse surface and a first reverse surface facing away from each other in a thickness direction;
a semiconductor element fixed to the first obverse surface;
a sealing resin covering the die pad portion and the semiconductor element; and
an insulating substrate including a first substrate metal layer, an insulating layer, and a second substrate metal layer that are stacked in an order stated,
wherein the insulating substrate includes a second obverse surface and a second reverse surface respectively facing same sides as the first obverse surface and the first reverse surface in the thickness direction,
the first reverse surface and the second obverse surface are fixed to each other,
the sealing resin includes a resin obverse surface and a resin reverse surface respectively facing same sides as the first obverse surface and the first reverse surface in the thickness direction, and
the second reverse surface is exposed from the resin reverse surface.

Clause 2.

The semiconductor device according to Clause 1, wherein
the second reverse surface and the resin reverse surface are flush with each other.

Clause 3.

The semiconductor device according to Clause 1 or 2, wherein the second reverse surface is formed by the second substrate metal layer.

Clause 4.

The semiconductor device according to any one of Clauses 1 to 3, wherein the insulating layer contains ceramic.

Clause 5.

The semiconductor device according to Clause 4, wherein the first substrate metal layer contains copper (Cu).

Clause 6.

The semiconductor device according to Clause 5, wherein the second substrate metal layer contains copper (Cu).

Clause 7.

The semiconductor device according to any one of Clauses 1 to 6, further comprising a first bonding member interposed between the lead and the insulating substrate,
wherein the insulating substrate includes a second-obverse-surface metal layer forming the second obverse surface,
the lead includes a substrate and a first-reverse-surface metal layer forming the first reverse surface,
the first bonding member includes a first base metal layer, and a first bonding metal layer and a second bonding metal layer disposed on opposite sides of the first base metal layer in the thickness direction,
the first-reverse-surface metal layer and the first bonding metal layer are joined by solid-state diffusion bonding, and
the second bonding metal layer and the second-obverse-surface metal layer are joined by solid-state diffusion bonding.

Clause 8.

The semiconductor device according to Clause 7, wherein the first-reverse-surface metal layer and the first bonding metal layer contain silver (Ag).

Clause 9.

The semiconductor device according to Clause 8, wherein the first bonding member includes a first intermediate metal layer interposed between the first bonding metal layer and the first base metal layer.

Clause 10.

The semiconductor device according to Clause 9, wherein the first intermediate metal layer contains nickel (Ni).

Clause 11.

The semiconductor device according to any one of Clauses 8 to 10, wherein the second bonding metal layer and the second-obverse-surface metal layer contain silver (Ag).

Clause 12.

The semiconductor device according to Clause 11, wherein the first bonding member includes a second intermediate metal layer interposed between the second bonding metal layer and the first base metal layer.

Clause 13.

The semiconductor device according to Clause 12, wherein the second intermediate metal layer contains nickel (Ni).

Clause 14.

The semiconductor device according to any one of Clauses 7 to 13, further comprising a second bonding member disposed between the lead and the semiconductor element,
wherein the semiconductor element includes a semiconductor layer and an element-reverse-surface metal layer disposed on a side toward the lead with respect to the semiconductor layer,
the lead includes a first-obverse-surface metal layer forming the first obverse surface,
the second bonding member includes a second base metal layer, and a third bonding metal layer and a fourth bonding metal layer disposed on opposite sides of the second base metal layer in the thickness direction,
the element-reverse-surface metal layer and the third bonding metal layer are joined by solid-state diffusion bonding, and
the fourth bonding metal layer and the first-obverse-surface metal layer are joined by solid-state diffusion bonding.

Clause 15.

The semiconductor device according to any one of Clauses 1 to 13, further comprising a bonding layer disposed between the first obverse surface and the semiconductor element.

Clause 16.

The semiconductor device according to Clause 15, wherein the bonding layer contains a sintered silver (Ag) material.

Clause 17.

A semiconductor device mount structure comprising: the semiconductor device according to any one of Clauses 1 to 16;
a heat sink; and
a sheet member interposed between the second reverse surface and the heat sink.

### REFERENCE NUMERALS

A10, A11, A20: Semiconductor device
B10: Semiconductor device mount body
11: First lead 12: Second lead
13: Third lead 20: Insulating substrate
20A: Second obverse surface 20B: Second reverse surface
30: Semiconductor element 31: First electrode
32: Second electrode 33: Third electrode
35: Semiconductor layer 40: Conductive member
41: First member 42: Second member
49: Second bonding layer 50: Sealing resin
51: Resin obverse surface 52: Resin reverse surface
53: First side surface 54: Second side surface
55: Opening 56: Mounting hole
60: First bonding member 70: Second bonding member
90: Heat sink 101: Substrate
102A: First-obverse-surface metal layer
102B: First-reverse-surface metal layer
111: Die pad portion 111A: First obverse surface
111B: First reverse surface 111C: Through-hole
112: Terminal portion 121: Wire pad portion
121A: Second obverse surface 122: Terminal portion
131: Wire pad portion 131A: Second obverse surface
132: Terminal portion 200: Insulating layer
201: First substrate metal layer
202: Second substrate metal layer
211: Second-obverse-surface metal layer
600: First base metal layer
601: First bonding metal layer
602: Second bonding metal layer
611: First intermediate metal layer
612: Second intermediate metal layer
700: Second base metal layer 701: Third bonding metal layer
702: Fourth bonding metal layer
711: Third intermediate metal layer
712: Fourth intermediate metal layer
901: Sheet material 902: Bolt

1. A semiconductor device comprising:
a lead including a die pad portion that includes a first obverse surface and a first reverse surface facing away from each other in a thickness direction;
a semiconductor element fixed to the first obverse surface;
a sealing resin covering the die pad portion and the semiconductor element; and
an insulating substrate including a first substrate metal layer, an insulating layer, and a second substrate metal layer that are stacked in an order stated,
wherein the insulating substrate includes a second obverse surface and a second reverse surface respectively facing same sides as the first obverse surface and the first reverse surface in the thickness direction,
the first reverse surface and the second obverse surface are fixed to each other,
the sealing resin includes a resin obverse surface and a resin reverse surface respectively facing same sides as the first obverse surface and the first reverse surface in the thickness direction, and
the second reverse surface is exposed from the resin reverse surface.

2. The semiconductor device according to claim 1, wherein the second reverse surface and the resin reverse surface are flush with each other.

3. The semiconductor device according to claim 1, wherein the second reverse surface is formed by the second substrate metal layer.

4. The semiconductor device according to claim 1, wherein the insulating layer contains ceramic.

5. The semiconductor device according to claim 4, wherein the first substrate metal layer contains copper (Cu).

6. The semiconductor device according to claim 5, wherein the second substrate metal layer contains copper (Cu).

7. The semiconductor device according to claim 1, further comprising a first bonding member interposed between the lead and the insulating substrate,
wherein the insulating substrate includes a second-obverse-surface metal layer forming the second obverse surface,
the lead includes a substrate and a first-reverse-surface metal layer forming the first reverse surface, the first bonding member includes a first base metal layer, and a first bonding metal layer and a second bonding metal layer disposed on opposite sides of the first base metal layer in the thickness direction,
the first-reverse-surface metal layer and the first bonding metal layer are joined by solid-state diffusion bonding, and
the second bonding metal layer and the second-obverse-surface metal layer are joined by solid-state diffusion bonding.

8. The semiconductor device according to claim 7, wherein the first-reverse-surface metal layer and the first bonding metal layer contain silver (Ag).

9. The semiconductor device according to claim 8, wherein the first bonding member includes a first intermediate metal layer interposed between the first bonding metal layer and the first base metal layer.

10. The semiconductor device according to claim 9, wherein the first intermediate metal layer contains nickel (Ni).

11. The semiconductor device according to claim 8, wherein the second bonding metal layer and the second-obverse-surface metal layer contain silver (Ag).

12. The semiconductor device according to claim 11, wherein the first bonding member includes a second intermediate metal layer interposed between the second bonding metal layer and the first base metal layer.

13. The semiconductor device according to claim 12, wherein the second intermediate metal layer contains nickel (Ni).

14. The semiconductor device according to claim 7, further comprising a second bonding member disposed between the lead and the semiconductor element,
wherein the semiconductor element includes a semiconductor layer and an element-reverse-surface metal layer disposed on a side toward the lead with respect to the semiconductor layer,
the lead includes a first-obverse-surface metal layer forming the first obverse surface,
the second bonding member includes a second base metal layer, and a third bonding metal layer and a fourth bonding metal layer disposed on opposite sides of the second base metal layer in the thickness direction,
the element-reverse-surface metal layer and the third bonding metal layer are joined by solid-state diffusion bonding, and
the fourth bonding metal layer and the first-obverse-surface metal layer are joined by solid-state diffusion bonding.

15. The semiconductor device according to claim 1, further comprising a bonding layer disposed between the first obverse surface and the semiconductor element.

16. The semiconductor device according to claim 15, wherein the bonding layer contains a sintered silver (Ag) material.

17. A semiconductor device mount structure comprising:
the semiconductor device according to claim 1;
a heat sink; and
a sheet member interposed between the second reverse surface and the heat sink.
